(19) United States
(12) Patent Application Publication
(10) Pub. No.: US 2009/0108445 A1
(43) Pub. Date: Apr. 30, 2009

(54) SUBSTRATE STRUCTURE AND SEMICONDUCTOR PACKAGE USING THE SAME

(75) Inventor: Jung Hua LIANG, Pingjhen City (TW)

Correspondence Address: LOWE HAUPTMAN HAM & BERNER, LLP, 1700 DIAGONAL ROAD, SUITE 300, ALEXANDRIA, VA, 22314, US

(73) Assignee: ADVANCED SEMICONDUCTOR ENGINEERING, INC., Kaohsiung (TW)

(21) Appl. No.: 12/193,422

(22) Filed: Aug. 18, 2008

(30) Foreign Application Priority Data
Oct. 31, 2007 (TW) 096140935

(51) Int. Cl. H01L 23/488; B05D 5/12

(52) U.S. Cl. 257/737; 428/201; 257/E23.023

(57) ABSTRACT

A substrate structure is provided. The substrate structure includes a substrate and a patterned wiring layer formed on the substrate. The patterned wiring layer includes a plurality of conductive traces. An isolation layer covers the patterned wiring layer and has an opening to expose a portion of at least one of the conductive traces therefrom. A plurality of conductive coatings covers the exposed portions of the conductive traces. The present invention further provides a semiconductor package with the above substrate structure.

### CROSS REFERENCE TO RELATED APPLICATION

This application claims the priority benefit of Taiwan Patent Application Serial Number 096140935 filed Oct. 31, 2007, the full disclosure of which is incorporated herein by reference.

### BACKGROUND OF THE INVENTION

1. Field of the Invention

The invention relates to a substrate structure and a semiconductor package using the same and more particularly, to a substrate structure and a semiconductor package using the same, wherein the patterned wiring layer of the substrate is provided with the conductive coatings for being electrically connected to a chip.

2. Description of the Related Art

Recently, a method named Super Juffit developed by Showa Denko K. K. has been put to practical use as a method of mounting chip components on a substrate. This Super Juffit method includes a step of forming an adhesive film on a surface of a copper circuit pattern formed on a substrate. Afterward, a solder power, which is a conductive powder, is applied to the adhesive film. A reflow process is then performed to melt the solder powder. Through these steps, a solder film is formed on the surface of the copper circuit pattern on the substrate.

The above-mentioned Super Juffit method has an advantage of a high pattern precision appropriate for a fine pitch layout. However, the solder film may corrode the copper circuit below and usually fails to be formed on the predetermined position on the copper circuit precisely by the reflow process.

### SUMMARY OF THE INVENTION

It is an object of the present invention to provide a substrate structure and a semiconductor package using the same, wherein the conductive coatings on the patterned wiring layer of the substrate are precisely formed on the predetermined positions on the conductive traces and do not corrode the conductive traces covered below. The substrate structure of the present invention can solve the problems occurred in the conventional Super Juffit technique.

In order to achieve the above object, the substrate structure of the present invention includes a substrate and a patterned wiring layer formed on the substrate. The patterned wiring layer includes a plurality of conductive traces. An isolation layer covers the wiring layer and has an opening to expose a portion of the each conductive trace therefrom. A plurality of conductive coatings covers the exposed portions of the conductive traces. Alternatively, the exposed portions of the conductive traces with the same electrical potential are covered with a single conductive coating. In order to facilitate the bonding of the electrical terminals of a chip to the conductive coatings, it is preferred that the width of the conductive coating is greater than that of the conductive trace covered below. In order to make the resulting conductive coatings have better flatness, the conductive trace is preferred to have two separated sections and the conductive coating is formed to cover the exposed portions of the two conductive trace sections. Alternatively, the conductive coating can cover two discontinuous conductive traces to have them electrically connected to each other.

The semiconductor package of the present invention includes a flip chip, which is electrically connected to the conductive coatings by a plurality of conductive bumps or conductive adhesive. A non-conductive paste is interposed between the flip chip and substrate.

The foregoing, as well as additional objects, features and advantages of the invention will be more readily apparent from the following detailed description, which proceeds with reference to the accompanying drawings.

### BRIEF DESCRIPTION OF THE DRAWINGS

FIG. 1 is a top view of the substrate structure of the present invention.

FIG. 2a is a cross-sectional view of the substrate structure taken from the line 2a-2a of FIG. 1.

FIG. 2b is a cross-sectional view of the substrate structure taken from the line 2b-2b of FIG. 1.

FIG. 3 is a cross-sectional view of the semiconductor package of the present invention.

### DETAILED DESCRIPTION OF THE PREFERRED EMBODIMENT

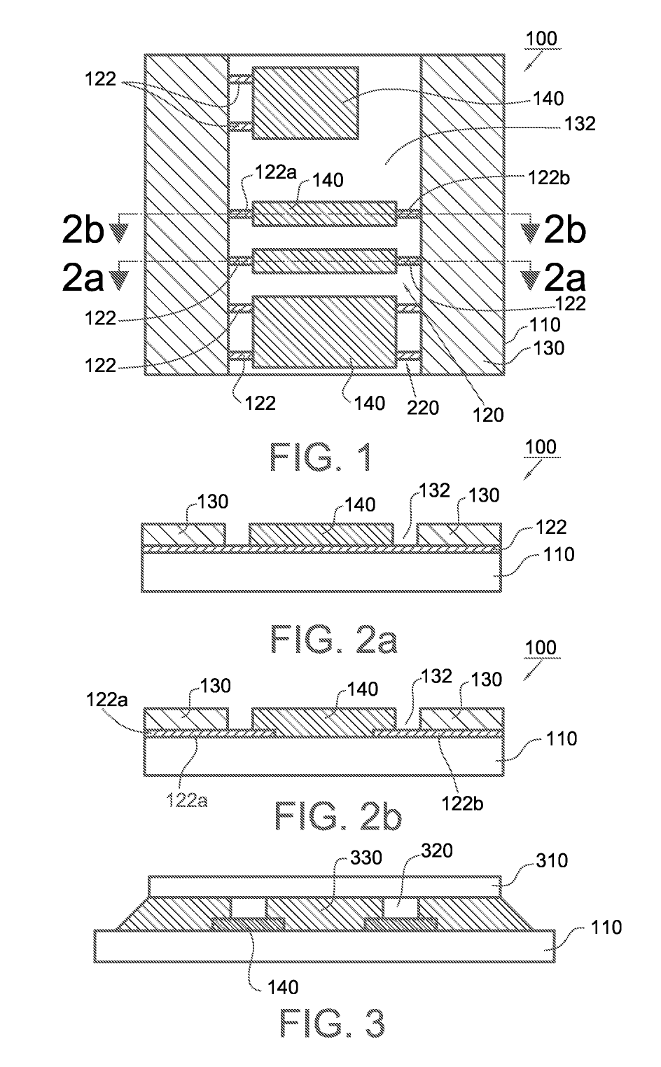

Referring to FIGS. 1 and 2a, the substrate structure 100 of the present invention includes a substrate 110 and a patterned wiring layer 120 formed on the substrate 110. The patterned wiring layer 120 includes a plurality of conductive traces 122 made of such as metal. An isolation layer 130, such as a solder mask covers the patterned wiring layer 120 and has an opening 132 to expose a portion of the each conductive trace 122 therefrom. A plurality of conductive coatings 140 made of conductive glass, such as indium tin oxide (ITO) covers the exposed portions of the conductive traces 122. Alternatively, the exposed portions of the conductive traces 122 with the same electrical potential are covered with a single conductive coating 140. In order to facilitate the bonding of the electrical terminals of a chip to the conductive coatings 140, it is preferred that the width of the conductive coating 140 is greater than that of the conductive trace 122 covered below. Since the conductive traces 122 are not usually even when being formed on the substrate 110, the surfaces of the conductive coatings 140 will also be uneven when being formed on the uneven conductive traces 122. This will cause the chip not easily to be bonded to the conductive coatings 140. To solve the above problem, referring to FIG. 2b, the conductive trace 122 is preferred to have two separated sections 122a and 122b and the conductive coating 140 is formed to cover the exposed portions of the conductive trace sections 122a and 122b. In this way, the resulting conductive coating 140 can electrically connect the conductive trace sections 122a and 122b to each other and its surface is much flatter to facilitate bonding to the electrical terminals of the chip. Besides, referring to FIG. 1 again, the conductive coating 140 can cover two discontinuous conductive traces 122 to have them electrically connected to each other.

The above conductive coatings 140 can be precisely formed on the predetermined positions on the conductive traces 122 by sputtering or evaporation with the use of masks. Moreover, the conductive coatings 140 are non-corrosive and therefore do not corrode the covered portions of the conductive traces 122. According to the substrate structure 100 of the present invention, the conductive coatings 140 on the conductive traces 122 can be bonded to the electrical terminals of a chip and therefore achieve the object of electrically connecting the chip to the conductive traces 122. It has the advantage of that the conventional Super Juffit technique has. On the other hand, with the discussion above, the conductive coatings 140 do not corrode the covered portions of the conductive traces 122 and can be precisely formed on the predetermined positions on the conductive traces 122. The substrate structure 100 of the present invention can solve the problems occurred in the conventional Super Juffit technique.

Referring to FIG. 3, the semiconductor package 300 of the present invention includes a chip 310, such as a flip chip. The chip 310 is electrically connected to the conductive coatings 140 on the substrate 110 by a plurality of conductive materials 320, such as solder stub bumps, gold stub bumps or conductive adhesive such as anisotropic conductive film (ACF). A non-conductive material 330, such as a non-conductive film or a non-conductive paste is interposed between the chip 310 and substrate 110 to protect the bumps 320 from damage due to moisture or stress.

Although the preferred embodiments of the invention have been disclosed for illustrative purposes, those skilled in the art will appreciate that various modifications, additions and substitutions are possible, without departing from the scope and spirit of the invention as disclosed in the accompanying claims.

What is claimed is:

1. A substrate structure, comprising:
a substrate;
a patterned wiring layer formed on the substrate and having a plurality of conductive traces;
an isolation layer covering the patterned wiring layer and having an opening to expose a portion of at least one of the conductive traces therefrom; and
a plurality of conductive coatings covering the exposed portion of the conductive trace.

2. The substrate structure as claimed in claim 1, wherein at least two of the conductive traces have the same electrical potential and the exposed portions of the two conductive traces are covered with the same one of the conductive coatings.

3. The substrate structure as claimed in claim 1, wherein the width of the conductive coating is greater than that of the conductive trace covered below.

4. The substrate structure as claimed in claim 1, wherein the exposed portions of at least two conductive traces are covered with the same one of the conductive coatings.

5. The substrate structure as claimed in claim 1, wherein the conductive traces are made of metal.

6. The substrate structure as claimed in claim 1, wherein the conductive coatings are made of conductive glass.

7. The substrate structure as claimed in claim 6, wherein the conductive glass is an indium tin oxide.

8. A semiconductor package, comprising:
a substrate;
a patterned wiring layer formed on the substrate and having a plurality of conductive traces;
an isolation layer covering the patterned wiring layer and having an opening to expose a portion of at least one of the conductive traces therefrom;
a plurality of conductive coatings covering the exposed portion of the conductive trace; and
a chip disposed on the substrate and electrically connected to the conductive coatings.

9. The semiconductor package as claimed in claim 8, wherein at least two of the conductive traces have the same electrical potential and the exposed portions of the two conductive traces are covered with the same one of the conductive coatings.

10. The semiconductor package as claimed in claim 8, wherein the width of the conductive coating is greater than that of the conductive trace covered below.

11. The semiconductor package as claimed in claim 8, wherein the exposed portions of at least two conductive traces are covered with the same one of the conductive coatings.

12. The semiconductor package as claimed in claim 8, wherein the chip is a flip chip, the semiconductor package further comprises a plurality of bumps, the flip chip are electrically connected to the conductive coatings by the bumps.

13. The semiconductor package as claimed in claim 12, wherein the bumps are solder bumps or gold bumps.

14. The semiconductor package as claimed in claim 8, wherein the chip is a flip chip, the semiconductor package further comprises an anisotropic conductive film, the flip chip are electrically connected to the conductive coatings by the anisotropic conductive film.

15. The semiconductor package as claimed in claim 12, further comprising a non-conductive film interposed between the flip chip and substrate.

16. The semiconductor package as claimed in claim 12, further comprising a non-conductive paste interposed between the flip chip and substrate.

17. The semiconductor package as claimed in claim 8, wherein the conductive traces are made of metal.

18. The semiconductor package as claimed in claim 8, wherein the conductive coatings are made of conductive glass.

19. The semiconductor package as claimed in claim 18, wherein the conductive glass is an indium tin oxide.
